(19) United States
(12) Patent Application Publication
(10) Pub. No.: US 2003/0190005 A1
(43) Pub. Date: Oct. 9, 2003

(54) Programmable capacitances for PLL loop and power supply noise filters

(76) Inventors: Brian Amick, Austin, TX (US); Claude Gauthier, Fremont, CA (US)

Correspondence Address: ROSENTHAL & OSHA L.L.P. / SUN, 1221 MCKINNEY, SUITE 2800, HOUSTON, TX, 77010, US

(21) Appl. No.: 10/115,660

(22) Filed: Apr. 4, 2002

(51) Int. Cl. H03D 3/24

(52) U.S. Cl. 375/376; 327/157

(57) ABSTRACT

A phase locked loop having a programmable capacitance stage is provided. The programmable capacitance stage facilitates a selective post-silicon adjustment of capacitance amounts between a PLL loop filter capacitance and a power supply noise filter capacitance, thereby allowing a designer to reduce capacitance area space wastage and to obtain an optimal PLL performance level.

### BACKGROUND OF INVENTION

As shown in FIG. 1, a typical computer system (10) has, among other components, a microprocessor (12), one or more forms of memory (14), integrated circuits (16) having specific functionalities, and peripheral computer resources (not shown), e.g., monitor, keyboard, software programs, etc. These components communicate with one another via communication paths (19), e.g., wires, buses, etc., to accomplish the various tasks of the computer system (10).

In order to properly accomplish such tasks, the computer system (10) relies on the basis of time to coordinate its various operations. To that end, a crystal oscillator (18) generates a system clock signal (referred to and known in the art as “reference clock” and shown in FIG. 1 as sys_clk) to various parts of the computer system (10). Modern microprocessors and other integrated circuits, however, are typically capable of operating at frequencies significantly higher than the system clock, and thus, it becomes important to ensure that operations involving the microprocessor (12) and the other components of the computer system (10) use a proper and accurate reference of time.

One component used within the computer system (10) to ensure a proper reference of time among a system clock and a microprocessor clock, i.e., “chip clock,” is a type of clock generator known as a phase locked loop, or “PLL” (20). The PLL (20) is an electronic circuit that controls an oscillator such that the oscillator maintains a constant phase relative to a system signal. Referring to FIG. 1, the PLL (20) has as its input the system clock, which is its reference signal, and outputs a chip clock signal (shown in FIG. 1 as chip_clk) to the microprocessor (12). The system clock and chip clock have a specific phase and frequency relationship controlled by the PLL (20). This relationship between the phases and frequencies of the system clock and chip clock ensures that the various components within the microprocessor (12) use a controlled and accounted for reference of time. When this relationship is not maintained by the PLL (20), however, the operations within the computer system (10) become non-deterministic.

FIG. 2 shows a PLL (20). The PLL (20) comprises a feedback loop that aligns the transition edge and frequency of the system clock (41) and a feedback loop signal (40). The PLL adjusts the output frequency in order to zero any phase and frequency difference between the system clock (41) and the feedback loop signal (40). The addition of a divide by N circuit (39) in the feedback loop enables the PLL to generate an output that has a frequency of N times the system clock (41) frequency. Multiplying the system clock is useful when the chip clock (42) must have a higher frequency than the system clock (41). The PLL core (36) adjusts the output frequency in order to zero any phase and frequency difference between the system clock (41) and the feedback loop signal (40). By adding the divide by N block (39), the chip clock (42) must be N times faster to allow the phase and frequency difference between the system clock (41) and the feedback loop signal (40) to zero. The PLL (20) may also have buffers (37, 38) to drive a larger resistive and/or capacitive load. The buffers (37, 38) are in the feedback loop so that any phase shift created by the buffers (37, 38) is zeroed by the PLL core (36).

Phase locked loops are basically second order feedback control systems. As such, the phase locked loop can be described in the frequency domain as having a damping factor and natural frequency. The damping factor and natural frequency are fixed by the selection of the PLL circuit parameters. The loop bandwidth is defined as the PLL input frequency at which the PLL output magnitude is 3 dB lower than the PLL output magnitude when the PLL input frequency is zero (DC). The loop bandwidth determines to a large degree the speed at which the phase locked loop can react to an undesired disturbance. The PLL should have a low loop bandwidth so that input clock error is adequately filtered. Power supply noise will, however, have a certain noise-versus-frequency characteristic. The PLL loop bandwidth may need to be increased to quickly correct disturbances present at the output of the PLL.

The loop bandwidth is dependent on a charge pump current and a loop filter capacitance. The more filter capacitance, the lower the loop bandwidth. For stability, the loop bandwidth is set relatively low, which entails using a large loop filter capacitance. In addition, due to the considerable tolerances of the capacitors across process variations, additional capacitance is usually added to ensure that a PLL is stable. However, more capacitance than is actually needed typically ends up being present.

A common performance measure of a PLL, besides input error tracking, is jitter. Jitter is the time domain error from poor spectral purity of an output. In other words, the output plus a known phase shift, should track the input. In a repeated output pattern, such as a clock signal, jitter is present when a transition that occurs from one state to another that does not happen at the same time relative to other transitions is said to have jitter. Jitter is a direct result of power supply noise. The amount of power supply noise is related to the amount of capacitance on the power supply, i.e., the more power supply capacitance, the lower the power supply noise.

However, after fabrication, due to the considerable tolerances of capacitors, capacitance may be much greater or less than had been designed for prior to fabrication. Also the amount of capacitance that can be placed on the power supply is often limited by area constraints. If the power supply capacitance is insufficient, a PLL's jitter performance can suffer, and hence, from a design perspective, maximum utilization of area to provide as much power supply noise filter capacitance as possible is necessary. Thus, after a PLL is fabricated, if it is found that the loop bandwidth is much lower than needed, a mask layer may have to be changed and re-fabricated to remove capacitance from the filter capacitance and add it to the power supply capacitance. In other cases, a designer may have planned ahead for high loop bandwidth, but ended up without enough capacitance for stability, in which case, the designer has to change a mask layer to add capacitance to the loop filter capacitance. Changing a mask layer is a costly and timely process. Thus, there is a need for a post-silicon, i.e., post-fabrication, capacitance adjustment technique to (1) allow the loop filter capacitance to be adjusted in order to find optimal stable loop bandwidth and (2) use unneeded loop filter capacitance for power supply noise filtering in order to reduce jitter. Such a technique would lead to optimal PLL performance.

### SUMMARY OF INVENTION

According to one aspect of the present invention, an integrated circuit comprises: a voltage controlled oscillator arranged to receive power from a power supply and responsive to a first signal applied at a first input thereof; and a programmable capacitance stage comprising a first capacitance disposed between the power supply and the first input and a second capacitance disposed between the power supply and ground, where the first capacitance and the second capacitance are selectively adjustable.

According to another aspect, a phase locked loop adapted to connect to a power supply and ground, comprises: a phase detector stage responsive to an input signal; a charge pump stage responsive to the phase detector stage, wherein the charge pump stage outputs a bias signal; a voltage controlled oscillator responsive to the bias signal; and a programmable capacitance stage that is selectively controlled to adjust a first capacitance between the power supply and ground and a second capacitance between the power supply and the bias signal.

According to another aspect, an integrated circuit comprises: oscillator means for controlling a frequency, where the oscillator means is responsive to a bias signal; and programmable capacitance means for selectively adjusting a first capacitance disposed between a power supply and the bias signal and a second capacitance disposed between the power supply and ground.

According to another aspect, a method for post-silicon adjustment of a phase locked loop comprises: selectively positioning a first capacitance amount between a power supply and a bias signal of the phase locked loop, where the selective positioning of the first capacitance amount occurs by control of at least one switching device; selectively positioning a second capacitance amount between the power supply and ground; and operating the phase locked loop such that the first capacitance amount serves as a loop filter capacitance and the second capacitance amount serves as a power supply noise filter capacitance.

According to another aspect, a method for optimizing a phase locked loop comprises: forming an integrated circuit having a voltage controlled oscillator arranged to receive power from a power supply and responsive to a first signal applied at a first input thereof and a programmable capacitance stage having a first capacitance disposed between the power supply and the first input and a second capacitance disposed between the power supply and ground; and adjusting the first capacitance and the second capacitance to optimize the phase locked loop.

Other aspects and advantages of the invention will be apparent from the following description and the appended claims.

### BRIEF DESCRIPTION OF DRAWINGS

FIG. 1 shows a typical computer system.

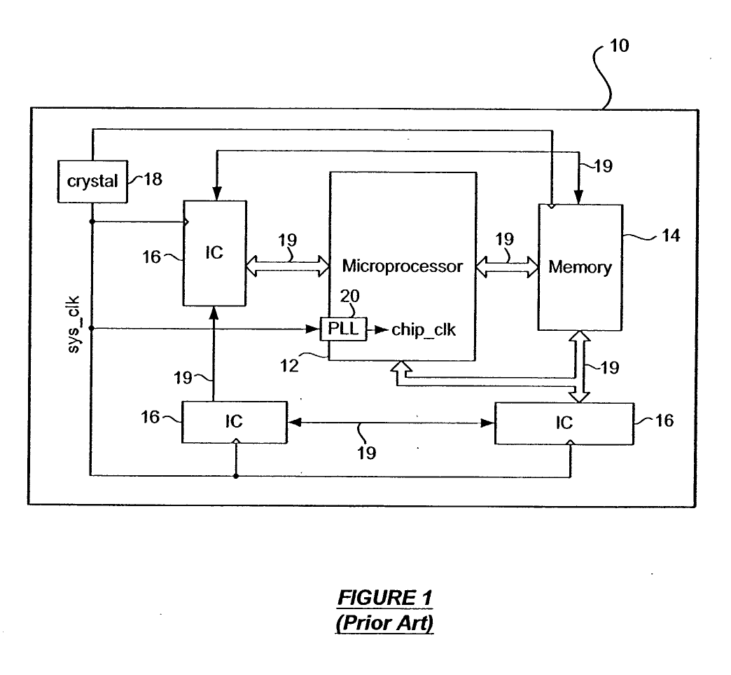

FIG. 2 shows a block diagram of a typical phase locked loop.

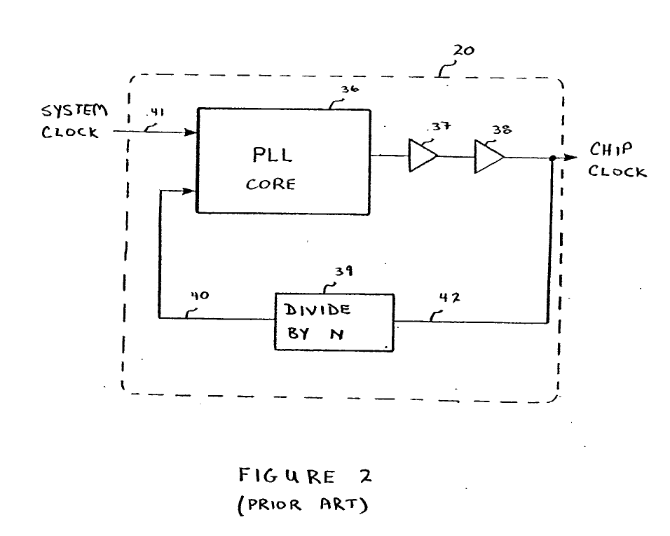

FIG. 3a shows a circuit diagram of a typical phase locked loop.

FIG. 3b shows a control diagram of a typical phased locked loop.

FIG. 4a shows a phase locked loop in accordance with an embodiment of the present invention.

FIG. 4b shows a programmable capacitance stage in accordance with an embodiment of the present invention.

FIG. 5a shows a circuit diagram of a programmable capacitance stage in accordance with an embodiment of the present invention.

FIG. 5b shows a circuit diagram of a programmable capacitance stage in accordance with another embodiment of the present invention.

FIG. 5c shows a circuit diagram of a programmable capacitance stage in accordance with another embodiment of the present invention.

### DETAILED DESCRIPTION

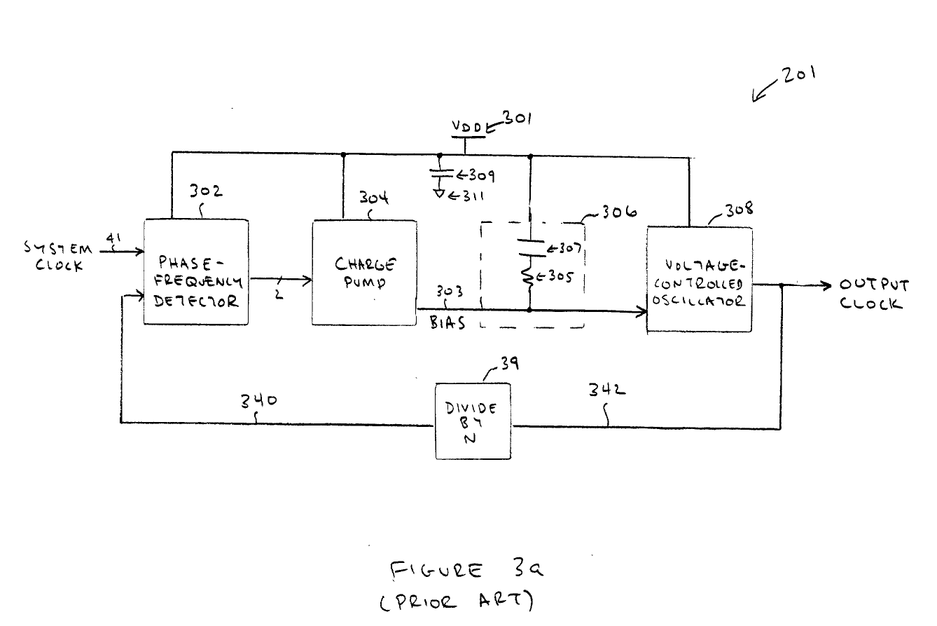

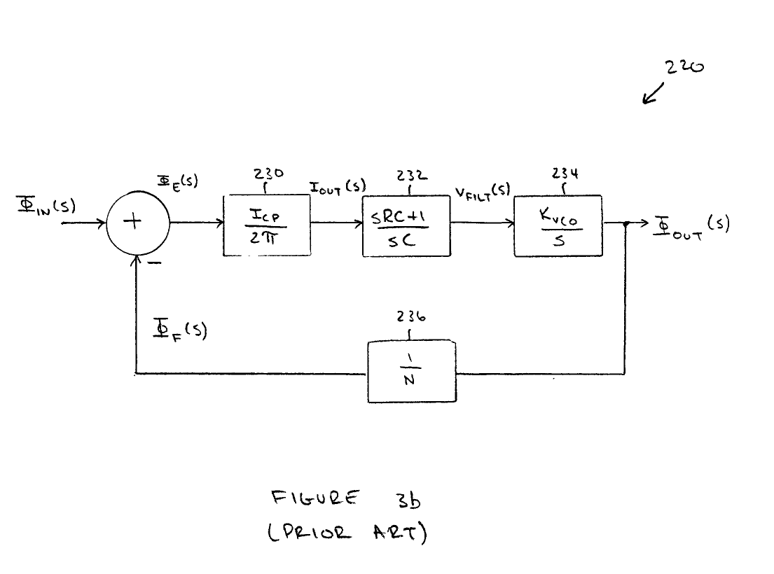

FIG. 3a shows a circuit diagram of a typical PLL (201). The PLL (201) has an input of system clock (41) that is used to create a phased output, output clock (342). The basic elements of a PLL core are a phase-frequency detector (302), charge pump (304), loop filter (306), and voltage-controlled oscillator (308). Output clock (342) may have a higher frequency than the system clock (41). A divide by N circuit (39) is used to reduce the frequency of the output clock (342) so that the system clock (41) and divided output clock (340) can be input to the phase-frequency detector (302). The phase-frequency detector (302) measures the phase and frequency difference between system clock (41) and divided output clock (340). The phase-frequency detector (302) produces signals that control a charge pump (304), typically up or down pulses (not shown), to increase or decease the net charge at the output of the charge pump (304). The charge pump (304) adds or removes charge from the loop filter (306). The loop filter (306) is composed of a resistance (305) and capacitance (307) in series connected to a supply voltage (301). The charge pump (304), via a bias signal BIAS (303), adjusts the voltage stored on the capacitor (307) in the loop filter (306). The voltage-controlled oscillator (308) produces the output clock (342) that has a frequency proportional to the voltage input to the voltage-controlled oscillator (308). Because the voltage input to the voltage-controlled oscillator (308) may be susceptible to power supply noise, the output clock (342) may jitter, and thus, some amount of power supply noise filter capacitance (309) is coupled to ground (311).

In FIG. 3b, the frequency response of the PLL (220) may be analyzed with a Laplace transform approximation, where the sample operation of the phase-frequency detector is ignored. This approximation is useful for loop bandwidths about a decade or more below the operating frequency of the PLL. This loop bandwidth constraint is also required for stability due to the reduced phase margin near the higher order poles that result from the delay around the sampled feedback loop. The modeled charge pump (230) adds or removes charge to its output depending on the state of input control signals, typically up or down pulses (not shown). Both pulses may be ‘on’ at the same time, however, if the up or the down pulse remains ‘on’ longer than the other, the net charge at the output of the charge pump (230) increases or decreases. The charge pump gain may be modeled as a linear gain versus phase error where I_{OUT}(s)/Φ_{E}(s)=I_{CP}/2π. The loop filter (232) may be modeled as a series combination of a capacitor, C, and a resistor, R, connected from I_{OUT} to ground. The loop filter (232) transforms the output of the charge pump, I_{OUT,} into the voltage-controlled oscillator input voltage, V_{FILT}. The Laplace transform of the series resistor and capacitor in the loop filter (232) is V_{FILT}(s)/I_{OUT}(s)=(sRC+1)/(sC). The transfer function of the capacitor and resistor shows that a zero is added that adds stability to the PLL loop. The voltage-controlled oscillator (234) outputs a clock that has a frequency proportional to the input voltage V_{FILT}. The Laplace transform of the voltage-controlled oscillator (234) is Φ_{OUT}(s)/V_{FILT}(s)=I_{CP}/V_{FILT}(s)=K_{VCO}/s. The closed-loop transfer function can now be derived as H(s)=Φ_{OUT}(s)/Φ_{IN}(s)=[(R K_{VCO}I_{CP}/2π)/(s+1/R C)]/[s²+s R C K_{VCO}I_{CP}/2πN C+K_{VCO}I_{CP}/2πN C]. H(s) is a second order system that has one pole from the loop filter (232) and one pole from the voltage-controlled oscillator (234), and one zero from the resistor, R, in the loop filter (232). The transfer function H(s) has a natural frequency ωₙ=(K_{VCO}I_{CP}/2πN C)^{0.5} and a damping factor ζ=R C ωₙ/2.

The loop bandwidth is defined as the frequency at which the output magnitude is 3 dB lower than when the input is DC. Loop bandwidth is not the same as natural frequency, although they are often close. Once ζ, ωₙ, K_{VCO}, and I_{CP} are chosen, the values for R and C can be determined for any selected loop bandwidth. Low loop bandwidth allows the PLL to filter input jitter. High loop bandwidth allows the PLL to follow and compensate for disturbances at the output of the PLL. A design tradeoff must be made in the loop bandwidth of the PLL. The value for C has a large effect on loop bandwidth and natural frequency. Optimizing the PLL loop bandwidth relates to balancing the effect of input jitter with the PLL loop's speed of response to compensate for output error disturbances.

Now referring back to FIG. 3a, by way of controlling the voltage controlled oscillator (308), the loop filter capacitance (307) controls the bandwidth of the feedback loop. In order to filter input clock jitter in the PLL while maintaining stability, there should be a sufficient amount of filter capacitance between BIAS (303) and the supply voltage (301). However, as mentioned previously, because capacitors have high tolerances, capacitance amounts present after fabrication may vary greatly from amounts designed for prior to fabrication. Thus, in actual implementation, optimal bandwidth and capacitance space efficiency is often not realized.

Another factor leading to jitter is power supply noise. Thus, in order to reduce power supply noise induced jitter, power supply noise filter capacitance (or decoupling capacitance) (309) is used. Unfortunately, the loop bandwidth is affected by many process technology factors and is generally constrained to levels below the lowest operating frequency for stability. For example, before a PLL is actually fabricated on a semiconductor, capacitance amounts for the loop filter capacitance (307) and power supply noise filter capacitance (309) are determined based on pre-silicon design. However, after fabrication, i.e., post-silicon, the predetermined capacitance amounts may not lead to optimal PLL performance due to area limitations among the loop filter capacitance (307) and power supply noise filter capacitance (309). Further, such area constraints lead to unsued capacitance, which, in turn, causes a wastage of space. More significantly, due to poor PLL performance resulting from the area limitations among the loop filter capacitance (307) and power supply noise filter capacitance (309), a PLL may have an undesired and limited delay range.

Moreover, although the filter capacitance (309) is beneficial for filtering purposes, it adversely affects the loop bandwidth of the PLL. Thus, it would be beneficial to be able to allocate unneeded filter capacitance to power supply capacitance both in order to limit the restrictions on loop bandwidth induced by the unneeded filter capacitance and for reducing power supply noise induced jitter. However, because capacitance amounts are not exactly known until after fabrication, efficient capacitance distribution is not realized, which, in turn, leads to sub-optimal performance.

The present invention improves upon typical PLL designs by using a programmable, i.e., controllable, capacitance stage. The programmable capacitance stage allows a designer to selectively allocate capacitances involving a PLL after fabrication so as to allow the designer to determine an optimal loop bandwidth point at which the lowest or a desired amount of output error is obtained. Accordingly, embodiments of the present invention relate to a PLL having a programmable capacitance stage. Embodiments of the present invention further relate to a technique for controlling a PLL post-silicon to achieve an optimal amount of output error and space efficiency.

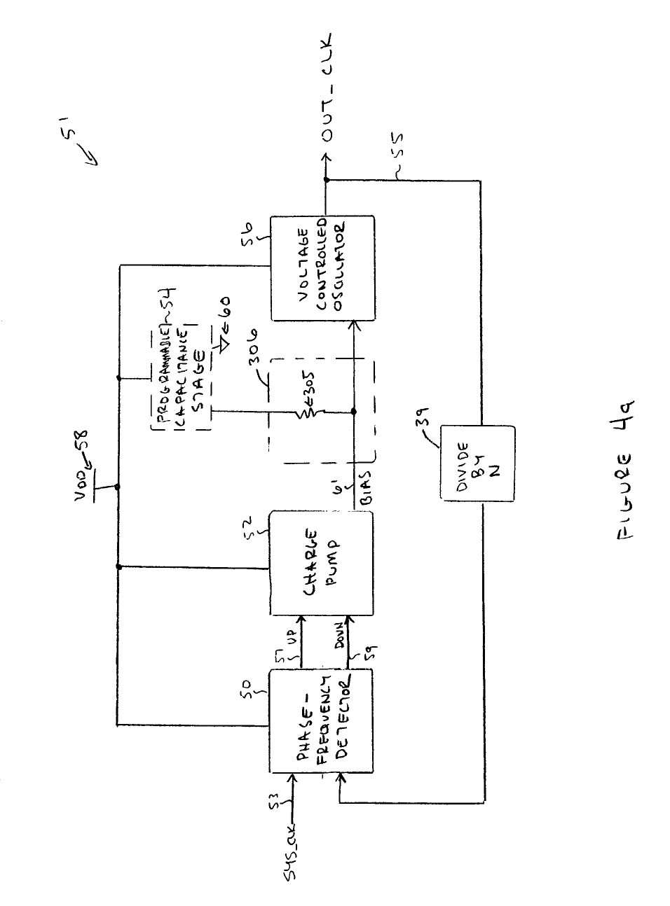

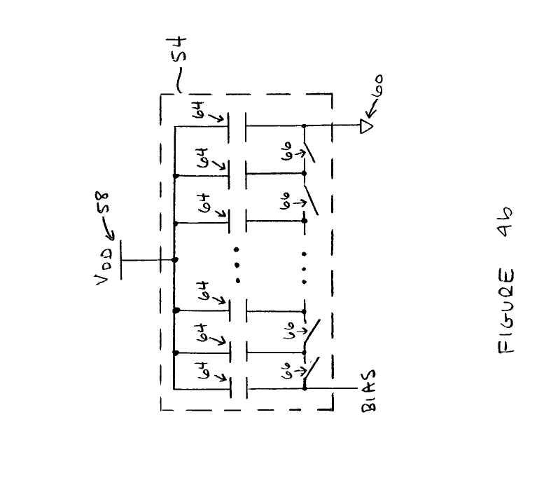

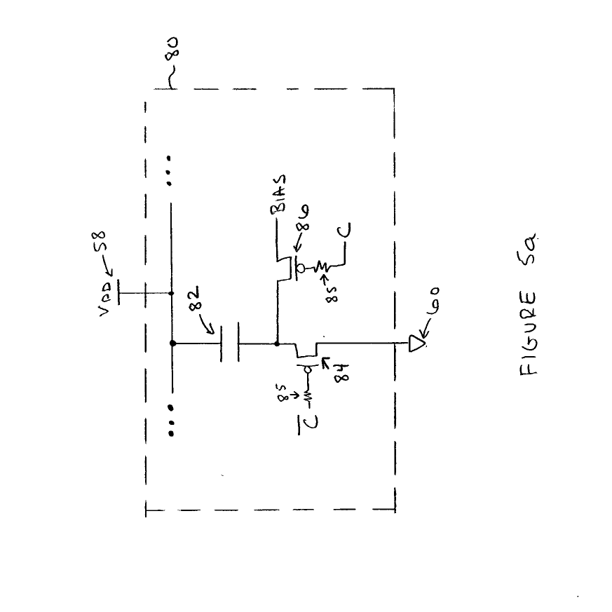

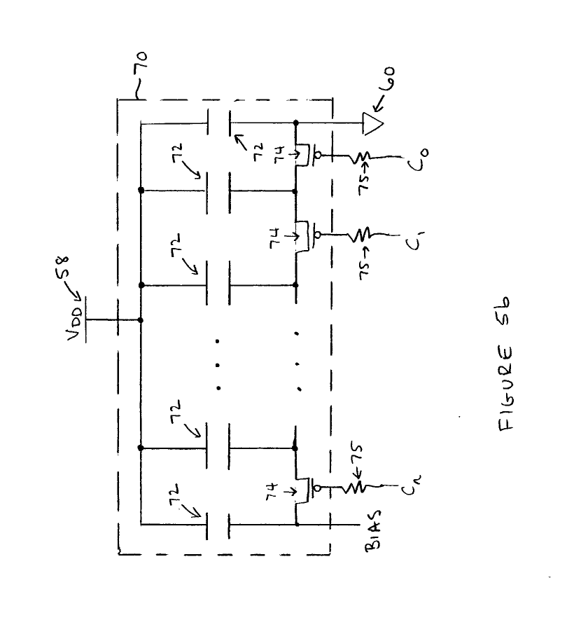

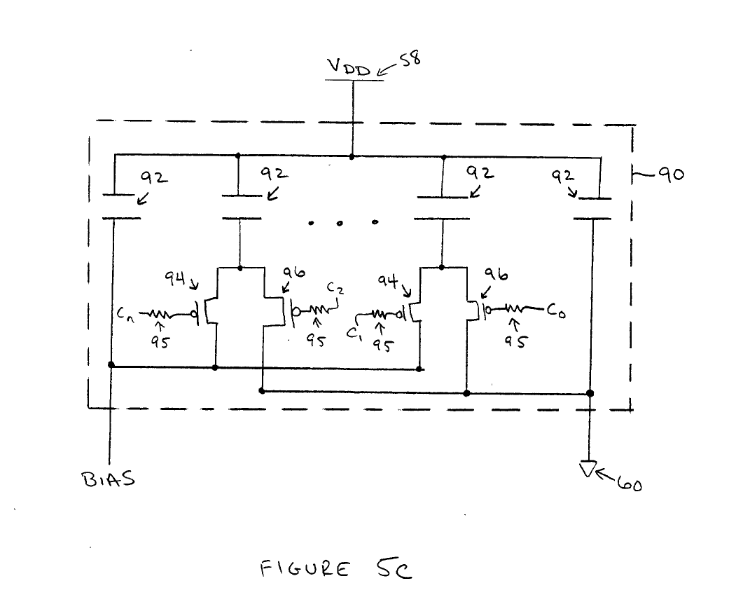

FIG. 4a shows a PLL (51) in accordance with an embodiment of the present invention. In FIG. 4a, system clock, SYS_CLK (53), is used as an input to a phase detector (50). The phase frequency detector (50) measures whether a phase difference between SYS_CLK (53) and an output (55) of a voltage controlled oscillator (56) is correct. In the case that the phase difference between SYS_CLK (53) and the output (55) of the voltage controlled oscillator (56) needs to be adjusted, the phase frequency detector (50) outputs UP (57) and/or DOWN (59) pulses to a charge pump (52). Depending on the UP (57) and DOWN (59) pulses, the charge pump (52) adds or removes charge from a pre-silicon amount of capacitance residing in a programmable capacitance stage (54) (a discussion of the programmable capacitance stage (54) is given below with reference to FIGS. 4b, 5a, 5b, and 5c), thereby changing a DC value of a BIAS signal (61), where BIAS (61) is used to control the delay of the voltage controlled oscillator (56). In other words, the charge pump (52) adjusts the voltage stored on the predetermined pre-silicon amount of capacitance residing in the programmable capacitance stage (54) between BIAS (61) and a potential. The output (55) of the voltage controlled oscillator (56) serves as an output, OUT_CLK, of the PLL (51) and as an input to a divide-by-N counter (39), which resides in a feedback path of the PLL (5 1). The divide-by-N counter (39) divides down the frequency of the output signal from the voltage controlled oscillator (56) and outputs the divided signal to the phase frequency detector (50) for comparison with SYS_CLK (53).

Still referring to FIG. 4a, by way of controlling the delay of voltage controlled delay stage (56), the pre-silicon loop filter capacitance amount controls the bandwidth of the feedback loop. In order to filter input clock jitter, there should be a sufficient amount of filter capacitance between BIAS (61) and the supply voltage (58). However, as mentioned previously, because capacitors have high tolerances, capacitance amounts present after fabrication may vary greatly from amounts designed for prior to fabrication. Thus, typically, in such a situation, the lowest amount of output error is not achieved, and PLL performance suffers. However, because of the presence of a programmable capacitance stage (54), the amount of capacitance allocated as loop filter capacitance for the PLL may be selectively adjusted after the PLL has been fabricated. Additionally, with the programmable capacitance stage (54), an optimal amount of capacitance may be positioned between the power supply (58) and ground (60), thereby optimally reducing the amount of jitter caused from power supply noise.

FIG. 4b shows a programmable capacitance stage (54) in accordance with an embodiment of the present invention. In FIG. 4b, a plurality of capacitances (64) having one terminal connected to the power supply (58) and another terminal connected to a series of switches (66) are shown. By controlling the states of the switches (66), a particular amount of capacitance may be allocated between the power supply (58) and BIAS and a particular amount of capacitance may be allocated between the power supply (58) and ground (60).

Thus, for example, a designer of a fabricated PLL may determine what amount of capacitance within a particular area needs to be positioned to adequately filter the power supply noise and then position the remaining capacitance to the loop filter capacitance. Alternatively, the designer may determine an optimal amount of loop filter capacitance and then allocate the remaining capacitance to filter the power supply noise. In another situation, the designer may selectively vary or tweak the amount of capacitance positioned for the loop filter capacitance and the power supply noise filter capacitance to determine an optimum area use of capacitance that leads to the lowest amount of output error and/or space wastage. Those skilled in the art will appreciate that by allowing a designer to selectively determine capacitance utilization, 100% of the capacitance for the PLL may be utilized.

Further, those skilled in the art will appreciate that the capacitances (64) shown in FIG. 4b may have different values, thus providing added variability to the programmable capacitance stage (54).

Further, those skilled in the art will appreciate that because higher bandwidth does not always lead to best overall performance, such a post-silicon adjustment design and technique allows a designer to optimize bandwidth while ensuring against capacitance wastage.

FIG. 5a shows a programmable capacitance stage (80) in accordance with an embodiment of the present invention. FIG. 5a shows an implementation of one capacitance-switch pair. Depending on a control signal, C, either a first switching device (84) or a second switching device (86) switches ‘on.’ If the first switching device (84) switches ‘on,’ then a capacitance (82) in the programmable capacitance stage (80) gets positioned between the power supply (58) and ground (60). Alternatively, if the second switching device (86) switches ‘on,’ then the capacitance (82) gets positioned between the power supply (58) and BIAS. Further, resistances (85) are positioned in series with the gates of the first and second switching devices (84, 86) to prevent noise in the control signal from coupling through the parasitics of the first and second switching devices (84, 86). Thus, by controlling the control signal, the amount of capacitance used to filter power supply noise and as a PLL loop filter capacitance is programmable so as to allow a designer to determine an optimal performance level for the PLL.

Those skilled in the art will understand that the programmable capacitance stage (80) shown in FIG. 5a is not limited to one capacitance-switch pair and may contain any desired amount of capacitances (82) and switches (84, 86).

FIG. 5b shows a programmable capacitance stage (70) in accordance with another embodiment of the present invention. In FIG. 5b, switching devices (74) are positioned along a node connected to one set of terminals for a set of capacitances (72), where the other set of terminals for the set of capacitances (72) is connected to the power supply (58). Depending on one or more control signals C₀, C₁, . . . Cₙ (in the case of multiple control signals, a “control word” may be thought of as being used), the states of the switching devices (74) are controlled so as to allow for the selective allocation of capacitances between the power supply (58) and BIAS and between the power supply (58) and ground (60). Further, resistances (75) are positioned in series with the gates of the switching devices (74) to prevent noise in the control signals from coupling through the parasitics of the switching devices (74).

FIG. 5c shows a programmable capacitance stage (90) in accordance with another embodiment of the present invention. In FIG. 5c, switching devices (94, 96) are positioned in series with capacitances (92) such that the states of switching devices (94, 96) connected to a particular capacitance (92) determine whether a terminal of that particular capacitance (92) is connected to BIAS or ground (60), i.e., whether that particular capacitance (92) serves as a loop filter or a power supply noise filter. The states of the switching devices (94, 96) are controlled by a plurality of control signals C₀, C₁, . . . Cₙ. Further, resistances (95) are positioned in series with the gates of the switching devices (94, 96) to prevent noise in the control signals from coupling through the parasitics of the switching devices (94, 96).

Those skilled in the art will appreciate that the various embodiments of a programmable capacitance stage shown in FIGS. 5a, 5b, and 5c facilitate a post-silicon selective allocation/adjustment of capacitance, wherein switches in the programmable capacitance stage are controlled by one or more control signals.

Advantages of the present invention may include one or more of the following. In some embodiments, because an amount of loop filter capacitance and power supply noise filter capacitance may be selectively allocated, an optimal use of capacitance leading to optimal PLL performance may be determined.

In some embodiments, because an amount of loop filter capacitance and power supply noise filter capacitance may be selectively adjusted after a PLL has been fabricated, a use of capacitance leading to minimal space wastage may be achieved.

In some embodiments, because an amount of PLL loop filter capacitance and power supply noise filter capacitance may be selectively adjusted after the PLL has been fabricated, jitter may be minimized, thereby optimizing PLL performance.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

what is claimed is:

1. An integrated circuit, comprising:
a voltage controlled oscillator arranged to receive power from a power supply and responsive to a first signal applied at a first input thereof; and
a programmable capacitance stage comprising a first capacitance disposed between the power supply and the first input and a second capacitance disposed between the power supply and ground,
wherein the first capacitance and the second capacitance are selectively adjustable.

2. The integrated circuit of claim 1, wherein the programmable capacitance stage comprises:
a selectable capacitance having a first terminal connected to the power supply; and
a switching device responsive to a control signal, wherein the switching device, based on the control signal, switches a second terminal of the selectable capacitance between the first input and ground.

3. The integrated circuit of claim 2, wherein the switching device is a metal-oxide semiconductor device.

4. The integrated circuit of claim 2, further comprising a resistance connected in series with a gate of the switching device.

5. A phase locked loop adapted to connect to a power supply and ground, comprising:
a phase detector stage responsive to an input signal;
a charge pump stage responsive to the phase detector stage, wherein the charge pump stage outputs a bias signal;
a voltage controlled oscillator responsive to the bias signal; and
a programmable capacitance stage that is selectively controlled to adjust a first capacitance between the power supply and ground and a second capacitance between the power supply and the bias signal.

6. The phase locked loop of claim 5, wherein the second capacitance is a loop filter capacitance of the phase locked loop.

7. The phase locked loop of claim 5, wherein the first capacitance is a power supply noise filter capacitance.

8. The phase locked loop of claim 5, wherein an output of the voltage controlled oscillator represents an output of the phase locked loop.

9. The phase locked loop of claim 8, wherein the phase detector stage inputs the output from the voltage controlled oscillator.

10. The phase locked loop of claim 5, further comprising:
a bias generator stage responsive to the bias signal, wherein the bias generator stage outputs to the voltage controlled oscillator.

11. The phase locked loop of claim 5, wherein the programmable capacitance stage comprises:
a selectable capacitance having a first terminal connected to the power supply; and
a switching device responsive to a control signal, wherein the switching device, based on the control signal, switches a second terminal of the selectable capacitance between the first input and ground.

12. The phase locked loop of claim 11, wherein the switching device is a metal-oxide semiconductor device.

13. The phase locked loop of claim 11, further comprising a resistance connected in series with a gate of the switching device.

14. The phase locked loop of claim 5, wherein the programmable capacitance stage is selectively controlled after the phase locked loop has been fabricated in an integrated circuit.

15. An integrated circuit, comprising:
oscillator means for controlling a frequency, wherein the oscillator means is responsive to a bias signal; and
programmable capacitance means for selectively adjusting a first capacitance disposed between a power supply and the bias signal and a second capacitance disposed between the power supply and ground.

16. A method for post-silicon adjustment of a phase locked loop, comprising:
selectively positioning a first capacitance amount between a power supply and a bias signal of the phase locked loop, wherein the selective positioning of the first capacitance amount occurs by control of at least one switching device;
selectively positioning a second capacitance amount between the power supply and ground; and
operating the phase locked loop such that the first capacitance amount serves as a loop filter capacitance and the second capacitance amount serves as a power supply noise filter capacitance.

17. The method of claim 16, further comprising:
controlling a voltage controlled oscillator of the phase locked loop using the bias signal;
phase comparing an output of the voltage controlled oscillator to a reference input to the phase locked loop; and
adjusting an amount of charge on the bias signal based on the phase comparison of the output of the voltage controlled oscillator and the reference input.

18. The method of claim 16, further comprising:
generating differential bias signals to the voltage controlled oscillator based on the bias signal.

19. A method for optimizing a phase locked loop, comprising:
forming an integrated circuit comprising:
a voltage controlled oscillator arranged to receive power from a power supply and responsive to a first signal applied at a first input thereof; and
a programmable capacitance stage comprising a first capacitance disposed between the power supply and the first input and a second capacitance disposed between the power supply and ground; and
adjusting the first capacitance and the second capacitance to optimize the phase locked loop.
